(19) United States
(12) Patent Application Publication
(10) Pub. No.: US 2022/0196749 A1
(43) Pub. Date: Jun. 23, 2022

(54) A Computer-Implemented Method for Electrochemical Impedance Spectroscopy and a Measurement Device for the Same

(71) Applicant: The European Union, Represented by the European Commission, Brussels (BE)

(72) Inventors: Akos Kriston, Ispra (IT); Andreas Pfrang, Alkmaar (NL)

(73) Assignee: The European Union, Represented by the European Commission, Brussels (BE)

(21) Appl. No.: 17/605,790

(22) PCT Filed: Apr. 30, 2020
(86) PCT No.: PCT/EP2020/061984

§ 371 Date: Oct. 22, 2021

(30) Foreign Application Priority Data
May 2, 2019 (EP) 19172388.1

(51) Int. Cl. G01R 31/389; H01M 10/48; G01R 31/3842

(52) U.S. Cl. CPC G01R 31/389; G01R 31/3842; H01M 10/48

(57) ABSTRACT

A computer-implemented method for electrochemical impedance spectroscopy of an electrochemical cell. The method comprises: applying a periodic perturbation with a predetermined carrier wave form on the potential or the current; simultaneously measuring an influence of the periodic perturbation on the other one of the potential or the current and a displacement or a stress of a working electrode of the electrochemical cell; extracting, using lock-in amplifiers, from the other one of the potential or the current an electrical parameter signal with the predetermined carrier wave form and from the displacement or a stress measurement signal a mechanical parameter signal with the predetermined carrier wave form. This enables measuring a response in two different physical parameters from applying a single periodic perturbation to yet another physical parameter. By analysing the extracted signal components, information on coupling effects between the electrochemical behaviour and the mechanical behaviour of the electrochemical cell are uncovered.

### TECHNICAL FIELD

The present invention relates to a computer-implemented method for electrochemical impedance spectroscopy of an electrochemical cell including a working electrode and at least one second electrode. The present invention also relates to a measurement device for electrochemical impedance spectroscopy of an electrochemical cell.

### BACKGROUND ART

Electrochemical cells, such as batteries, are an important part of various applications, such as hybrid and full electric vehicles and grid-related electricity storage. Quite recently, Li-ion batteries have replaced lead acid batteries as leading the battery market in terms of revenue. This is mainly due to a superior energy density of Li-ion batteries compared to conventional batteries. While, Li-ion batteries will continue to be important, it is expected that other types of batteries may offer an even still higher energy density. However, for other types of batteries, several non-electrochemical issues, such as mechanical deformation, should be investigated.

Battery materials can expand significantly due to chemical and electrochemical reactions, such as lithiation in the case of Li-ion batteries. If, simultaneously with the electrochemical reaction, the battery material experiences external pressure, expansion can be suppressed and stresses build up inside the battery material (diffusion induced stress). Repeated expansion and contraction, as well as stresses inside battery materials or at interfaces, can lead to mechanical damage and therefore degradation or even failure. While, in current Li-ion batteries (e.g. with a graphite anode and a nickel manganese cobalt oxide cathode), electrode thickness changes are limited to a few percent, mechanical damage has been reported.

It is expected that mechanical effects and degradation will become even more important in the future. For example, already the addition of silicon to the graphite anode of Li-ion batteries leads to significantly higher stress or expansion. This is caused by the expansion of silicon with lithiation being 10 times larger when compared to the expansion of graphite. Other candidate electrode materials for new battery concepts also often show significantly increased expansion when compared to conventional Li-ion electrodes.

Moreover, in current Li-ion batteries, the liquid electrolyte can accommodate mechanical stresses at least partially and thereby helps avoid degradation and damage. However, in solid state batteries, which are considered as a promising future battery technology, a solid electrolyte is used instead, which naturally has a reduced capability of accommodating mechanical stresses. Specifically designed solid/solid interfaces will be required in solid state batteries to ensure ion mobility and mechanical integrity at the same time.

For other solid-sate or partially solid-state electrochemical systems, such as porous fuel cells, where water uptake surface restructuring and degradation can cause volume change and stress, the understanding of interaction between mechanical and electrochemical behaviour can be also crucial.

In summary, mechanical effects are expected to play a crucial role in the design of future electrochemical systems, such as batteries, in particular for battery lifetime. Additionally, safety aspects have to be considered as, for example, a mechanical failure could, under severe conditions, lead to short circuiting.

In order to address the impact of mechanical effects on lifetime and safety of implantable electrodes, Stefan B. Rieger et al. in “Concept and Development of an Electronic Framework Intended for Electrode and Surrounding Environment Characterization In Vivo”, Sensors 2017, 17, 59, doi: 10.3390/s17010059, published on Dec. 30, 2016 propose a sensor framework to analyse the behaviour of an electrode, in particular during stimulation. The sensor framework includes an electrochemical impedance sensor, a stress sensor and a temperature sensor to measure the behaviour of the working electrode and the counter electrode of the electrochemical cell. The stress sensor and the temperature sensor are both connected to a single lock-in-amplifier to ensure that small changes in resistance are detectable in the noise, i.e. the lock-in-amplifier improves the signal-to-noise ratio of the stress and temperature measurement.

The electrochemical impedance sensor is used to perform Electrochemical Impedance Spectroscopy (EIS) by applying a periodic perturbation to the voltage and analysing the perturbed current signal. The stress sensor and the temperature sensor are combined in a Wheatstone bridge arrangement which was excited by a sinusoidal, i.e. periodic, perturbation. Changes in resistance due to the periodic perturbation were measured using the lock-in amplifier.

### DISCLOSURE OF THE INVENTION

It is an object of the present invention to provide an improved method of measuring electrochemical and mechanical properties of an electrochemical cell.

This object is achieved according to the invention with a computer-implemented method for electrochemical impedance spectroscopy of an electrochemical cell including a working electrode and at least one second electrode, the method comprising the steps of: a) applying a periodic perturbation with a predetermined carrier wave form on a first electrical parameter of the electrochemical cell, the first electrical parameter being one of a potential and a current; b) simultaneously measuring an influence of the periodic perturbation on a second electrical parameter of the electrochemical cell and on a mechanical parameter of the working electrode, the second electrical parameter being the other one of the potential and the current, the mechanical parameter being one of a displacement and a stress; c) extracting, using a first lock-in amplifier, from the second electrical parameter measurement signal a second electrical parameter signal with the predetermined carrier wave form; and d) extracting, using a second lock-in amplifier, from the mechanical parameter measurement signal a mechanical parameter signal with the predetermined carrier wave form.

The method according to the present invention enables measuring a response in two different physical parameters from applying a single periodic perturbation to yet another physical parameter. In particular, one of the electrical parameters of the electrochemical cell is periodically perturbed, i.e. current or voltage, while the effect of this perturbation is measured simultaneously on both the other electrical parameter and a mechanical parameter, i.e. stress or displacement, of the electrochemical cell. By using two lock-in amplifiers, i.e. one for each measured parameter, it is possible to retrieve, from the measurement signals, the signal component having the same carrier wave form as the applied perturbation. By analysing the extracted signal components, i.e. the second electrical parameter signal and the mechanical parameter signal, it is possible to ascertain information on coupling effects between the electrochemical behaviour and the mechanical behaviour of the electrochemical cell, thus improving on existing methods that were not able to ascertain any coupling behaviour.

It should be pointed out that the method used by the sensor framework of the Stefan B. Rieger et al. publication discussed above was not able to ascertain any coupling behaviour since the perturbations and measurements used for EIS and for the Wheatstone bridge (which includes a stress measurement), were wholly separate from one another without any of the required hardware components being connected to one another.

In an embodiment of the present invention, the method further comprises the following step: e) transforming the second electrical parameter signal and the mechanical parameter signal into the frequency domain to determine a coupling between the electrical parameters and the mechanical parameter of the electrochemical cell.

Frequency domain analysis of dynamical systems is a well-known technique and used in multiple fields of science. A state equation of a system, which can be electrical, electrochemical or mechanical consists of ordinary or partial differential equations. The transfer function, which describes the system behaviour under various excitations, can be calculated by using a Laplace transformation of the original equations. It transforms the time behaviour of the system to the frequency domain. This general method can be applied to electrical circuits, electrochemistry or mechanical stability problems. Consequently, transforming the second electrical parameter signal and the mechanical parameter signal into the frequency domain is a practical, reliable and fast method to determine the coupling behaviour between the electrical parameters and the mechanical parameter of the electrochemical cell.

In an embodiment of the present invention, step a) comprises applying the periodic perturbation to the potential, the periodic perturbation preferably having an amplitude between 1 to 50 mV, in particular between 5 to 20 mV.

The technique of voltammetry, i.e. perturbing the potential, is used more widely than its inverse counterpart amperometry, i.e. perturbing the current. Consequently, applying the periodic perturbation to the potential is a practical and reliable method to perturb the electrochemical cell. Moreover, the preferred amplitude of the potential perturbation is selected in order to preserve the linearity of the system according to the basic theory of electrochemical impedance spectroscopy. It has also been found that such amplitude values are within the safety zone of the electrochemical cell.

In a preferred embodiment of the present invention, the method further comprises the step of determining the electroactive material electrical complex impedance Z_{E}, the electro-mechanical impedance Z_{ε} and the chemo-mechanical impedance Z_{Li} using the following equations

$${Z}_{E} = \frac{Δ E}{Δ I} = {Z}_{e} - {R}_{Ω} ;$$

$${Z}_{ɛ} = \frac{Δɛ}{Δ E} = {LZ}_{m} \frac{{Z}_{e}}{{Z}_{e} - {R}_{Ω}} or {Z}_{ɛ} = L \frac{Δɛ}{Δ {Y}_{I}} \frac{Δ {Y}_{I}}{Δ E} = {LZ}_{I} {Z}_{E}^{- 1} ; and$$

$${Z}_{Li} = \frac{Δɛ}{Δ {c}_{Li}} ( ω ) = j ω F \frac{{Z}_{ɛ}}{1 - {Z}_{ɛ} j ω {C}_{dl}} ,$$

where Zₑ is the electrical impedance of the electrochemical cell, Zₘ is the mechanical impedance of the electrochemical cell, E is the electrode potential, R_{Ω} is the Ohmic drop, ε is the strain, C_{dl} is the double layer capacitance, L is a conversion factor, C_{Li} is a Li-ion concentration in the working electro-active material, F is the Faraday constant, j is the imaginary number and ω is the frequency of the periodic perturbation.

The impedances quantifies the effective resistance of the electrochemical cell. By determining the electroactive material electrical complex impedance, the electro-mechanical impedance and the chemo-mechanical impedance, it is possible to ascertain the effects of the applied periodic perturbation on the various effective resistances.

In an embodiment of the present invention, step b) comprises any one of the following: using a mechanical coupler to measure the displacement; using a laser interference technique to measure the displacement; and using a beam bending technique to measure the stress. Preferably, a contactless laser interference technique is used to measure the displacement.

By using contactless laser interference technique, influence on the mechanical behaviour of the electrochemical cell is minimized. The influence could, for example, be due to the mass of the mechanical coupler, which mass induces a moment of inertia.

In an embodiment of the present invention, the periodic perturbation has a frequency between 0.1 mHz and 10 MHz, in particular between 1 mHz and 1 MHz, more in particular between 1 mHz and 100 kHz, and most in particular between 1 mHz and 20 Hz.

A range between 0.1 mHz and 10 MHz is the current capability of the known impedance spectroscopes, while the narrower range of 1 mHz and 1 MHz is typically the electrochemically most active frequency range. Moreover, the further narrower range of between 1 mHz and 100 kHz is chosen as conventional displacement sensors are particularly sensitive in this range. Furthermore, the narrowest range of between 1 mHz and 20 Hz is typically the mechanically active region.

In an embodiment of the present invention, step a) comprises choosing the predetermined carrier wave form as a signal including a plurality of different frequencies.

Using a single predetermined carrier wave form including a plurality of different frequencies, i.e. a superposition of multiple frequency values, allows a faster calculation of the electro-mechanical and chemo-mechanical impedance, when compared to sequentially applying different predetermined carrier wave forms having a different frequency.

The object according to the invention is also achieved with a measurement device for electrochemical impedance spectroscopy, the device comprising: an electrochemical cell including a working electrode and at least one second electrode; a potential sensor connected to the working electrode and the at least one second electrode to measure potential of the electrochemical cell; a current sensor connected to the working electrode and the at least one second electrode to apply or measure current of the electrochemical cell; a mechanical sensor configured to measure a mechanical parameter of the working electrode, the mechanical parameter being one of a displacement and a stress; perturbation means for periodically perturbing a first electrical parameter of the electrochemical cell, the first electrical parameter being one of the potential and the current; a first lock-in amplifier connected to one of the potential sensor and the current sensor; a second lock-in amplifier connected to the mechanical sensor; and a controller configured to execute the steps of the method described above.

The advantages of the measurement device are the same as the computer-implemented method described above.

In an embodiment of the present invention, the at least one second electrode comprises a counter electrode and a reference electrode, the potential sensor being connected to the reference electrode and the current sensor being connected to the counter electrode.

Such a three-electrode electrochemical cell solves the problem of the two-electrode electrochemical cell where it is difficult for the sole second electrode to maintain a constant potential while passing current to counter perturbations at the working electrode.

In an embodiment of the present invention, the mechanical sensor is a contactless displacement sensor. The advantages of using a contactless displacement has been described above with reference to a contactless laser interference technique.

In an embodiment of the present invention, the electrochemical cell is one of a Li-ion, Na-ion battery and a solid-state Li battery or where the electrochemical cell comprises an electroactive material with a measurable volume change in use.

In an embodiment of the present invention, the device further comprises: a housing having an opening; and a flexible membrane to cover said opening, the flexible membrane including an outer region fixedly attached to the housing, a substantially flat inner region to which the working electrode is attached and a middle region connecting the outer region and the inner region, in particular by at least two folding lines, wherein the middle region is provided with at least one folding line.

As has been described above, it is advantageous if the working electrode experiences as little moment of inertia as possible caused by the mechanical parameter measurement. In this embodiment, the membrane is specifically designed with at least one folding line in the middle region. The at least one folding line allows the inner region of the membrane to easily move upwards and downwards since the middle region area adjacent the folding line is able to fold inwards and outwards. Distortions in the displacement of the working electrode are thus minimised.

Preferably, the flexible membrane has a cylindrical symmetry. This excludes other configurations, such as a planar symmetry which is less effective in minimising displacement distortions.

Preferably, the flexible membrane is made of a conducting material.

In this embodiment, the membrane acts as the current collector of the electrochemical cell and directly touches the active material. While it is possible to use a membrane made of a non-conducting material, the working electrode then needs to be connected to the active material to close the circuit. This latter configuration breaks the symmetry and may distort both the mechanical and electrochemical impedance measurements.

Preferably, an outer surface of the flexible membrane opposite to the working electrode is reflective. This is especially beneficial in combination with a contactless laser interference technique to measure the displacement as the laser beam is now more easily reflected.

### BRIEF DESCRIPTION OF THE DRAWINGS

The invention will be further explained by means of the following description and the appended figures.

FIG. 1 shows a schematic representation of a measurement device according to the present invention.

FIG. 2 shows a flow-chart of a computer-implemented method for electrochemical impedance spectroscopy by using the measurement device of FIG. 1.

FIG. 3 shows a schematic representation of a measurement device according to a preferred embodiment of the present invention.

FIG. 4 shows a top view of the flexible membrane used in the measurement device of FIG. 3.

FIG. 5 shows a top view of an alternative flexible membrane that may be used in the measurement device of FIG. 3.

FIG. 6 shows the measurement device of FIG. 3 with a different membrane.

FIG. 7 shows an example of the time domain behaviour of an electrochemical cell determined using a measurement device according to the present invention.

FIG. 8 shows the measured Zₑ in Nyquist and in Bode representation (inset) of the electrochemical cell measurement of FIG. 7.

FIG. 9 shows the measured Zₘ in Bode representation of the electrochemical cell measurement of FIG. 7.

FIG. 10 shows the electrochemical impedance without the Ohmic resistance and the capacitive impedance of the electrochemical cell measurement of FIG. 7.

FIG. 11 shows the calculated electro-mechanical Z_{ε} and chemo-mechanical Z_{Li} resistances of the electrochemical cell measurement of FIG. 7.

### DESCRIPTION OF THE INVENTION

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes. The terms so used are interchangeable under appropriate circumstances and the embodiments of the invention described herein can operate in other orientations than described or illustrated herein.

Furthermore, the various embodiments, although referred to as “preferred” are to be construed as exemplary manners in which the invention may be implemented rather than as limiting the scope of the invention.

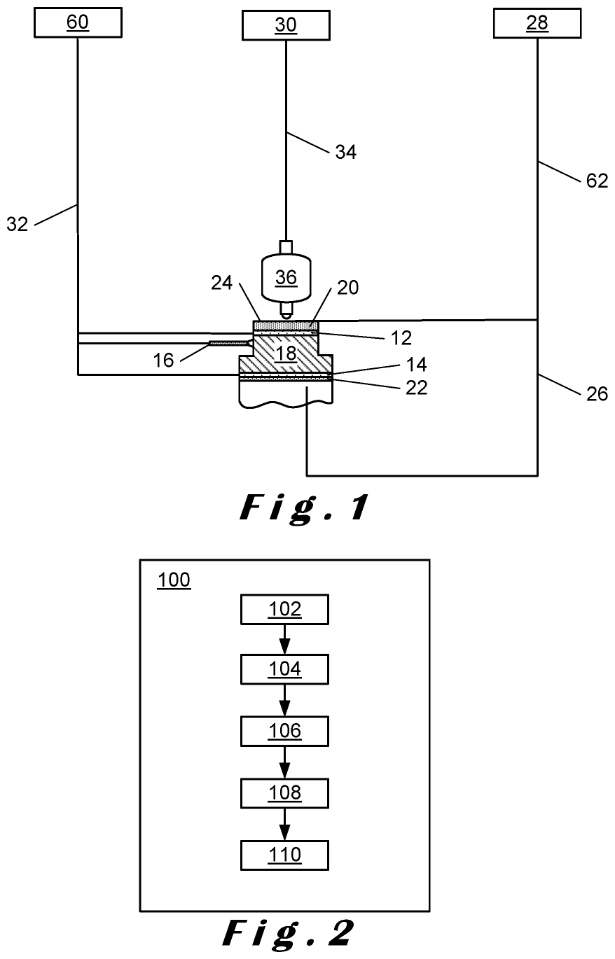

FIG. 1 shows a schematic representation of a measurement device according to the present invention. The measurement device uses a typical three-electrode system, which includes a working electrode 12 (e.g. made from graphite, silicon, Li-Nickel-Cobalt-Manganase-Oxide), a counter electrode 14 (e.g. made from a Li or Na metal) and a reference electrode 16 (e.g. made from a Li metal). The separator 18 (e.g. made from glass frit or a porous ceramic material) is located between the working electrode 12 and the counter electrode 14 and is in direct ionic contact with both electrodes 12, 14. Both electrodes 12, 14 and the separator 18 are soaked with electrolyte (e.g. LiPF₆ diluted in Ethylene-Carbonate and Dimethyl-Carbonate). On the side of the electrode surfaces 12, 14 opposite to the separator 18, current collectors 20, 22 are attached that are connected to one another via conduit 26 to have a closed circuit. The top current collector 20 is attached to a membrane 24, which may, for example, be used to seal a housing (not shown) in which the electrodes 12, 14, 16 and the separator 18, i.e. the entire electrochemical cell, are shielded from the outside environment.

It will be readily appreciated that the measurement device may also use a common two-electrode configuration where a single electrode acts as both the counter electrode and the reference electrode. In this case the electrical impedance is affected by the impedance of the counter electrode, therefore the accuracy of the measurement is reduced. Moreover, four or more electrodes may also be used in conjunction with the measurement device according to the present invention.

The working electrode 12, which makes contact with the electrolyte soaked in the separator 18, applies a desired potential versus the reference electrode 16 in a controlled way by using a potentiostat 60 connected to the working electrode 12, the counter electrode 14 and the reference electrode 16 by conduit 32. After applying the perturbation, the potential of the working electrode 12 differs from the steady state value and the transfer of charge to and from the electrolyte and the counter electrode 14 occurs. In this way, the working electrode 12 acts as a first half cell. The reference electrode 16 defines the potential of half cell with a known and perturbation independent potential. Its role is to act as a reference in measuring and controlling the potential of the working electrode 12 and should at no point pass any current. The counter electrode 14 passes all the current needed to balance the current observed at the working electrode 12 by conduit 32.

In general the three-electrode system is used for testing an electrochemical cell, such as a Li-ion battery, a Na-ion battery or a solid-state Li battery. However, the measurement device may be used to test any kind of electrochemical cell having an electroactive material with a measurable volume change in use.

The working electrode 12 and the counter electrode 14 enable to generate a current signal, measured in circuit 26, that is transferred, via connection 62, to a first lock-in amplifier 28.

The measurement device is further provided with a displacement sensor 36 to measure the displacement of the working electrode 12 by means of the membrane 24 displacement. The displacement signal is transferred, via connection 34, to a second lock-in amplifier 30. In the embodiment of FIG. 1, the displacement sensor 36 relies on mechanical contact with the membrane 24.

The measurement device also includes a controller (not shown), such as a processing unit with a memory, to control the operation of the device as described below. The method 100 of operating the measurement device will be described with reference to the flow-chart in FIG. 2.

In a preliminary step, the equilibrium (open circuit) value of the first electrical parameter (e.g. open circuit potential) is applied by the potentiostat until the steady state (i.e. constant) of the second electrical and the mechanical parameter are established.

In step 102, a periodic perturbation with a predetermined carrier wave form is applied on a first electrical parameter of the electrochemical cell, the first electrical parameter being one of a potential and a current. In the illustrated embodiment, the first electrical parameter is the potential. Preferably, the periodic perturbation has an amplitude between 1 to 50 mV, in particular between 5 to 20 mV, and a frequency between 0.1 mHz and 10 MHz, in particular between 1 mHz and 1 MHz, more in particular between 1 mHz and 100 kHz, and most in particular between 1 mHz and 20 Hz.

The amplitude of the potential perturbation is selected in order to preserve the linearity of the system according to the basic theory of electrochemical impedance spectroscopy. It has also been found that such amplitude values are within the safety zone of the electrochemical cell. Further, a range between 0.1 mHz and 10 MHz is the current capability of the known impedance spectroscopes, while the narrower range of 1 mHz and 1 MHz is typically the electrochemically most active frequency range. Moreover, the further narrower range of between 1 mHz and 100 kHz is chosen as conventional displacement sensors are particularly sensitive in this range. Furthermore, the narrowest range of between 1 mHz and 20 Hz is typically the mechanically active region. It will be readily appreciated that these values are only indicative and that other values may be used depending on the mechanical properties of the material under investigation.

Step 102 may include applying a periodic perturbation with a predetermined carrier wave form including a plurality of different frequencies. Such a superposition of multiple frequency values can be applied also and the response of the system can be measured to allow measuring the quantities Zₑ, Zₘ as described below. After that the evaluation and calculation of the electro-mechanical and chemo-mechanical impedance are identical as described below. The upside of such a superposed carrier wave form is that the method is faster, but accuracy may be lost.

Alternatively, as described in greater detail below, the method 100 may be repeated multiple times to quantify the behaviour at different frequencies by varying the frequency of the single-frequency predetermined carrier wave forms in subsequent iterations.

In step 104, the response, i.e. the influence of the periodic perturbation, of the second electrical parameter and the mechanical parameter is measured. Generally, the second electrical parameter is the other one of the potential and the current, i.e. the current in the measurement device, and the mechanical parameter is one of displacement and stress, i.e. displacement in the measurement device.

The aim of the measurement device is to determine the transfer function Z which transfers any multiple input W to any multiple output Y namely

Y=Z(W) (1)

In the following any perturbed input or output signal χ is expressed in the following form

χ=χ̅+Re{Δχ exp jωt} (2)

where χ̅ represents the steady state of the input, Re{ } is the real part of the input, Δχ is a complex time independent quantity, ω is the frequency of the perturbation and j is the imaginary number. Furthermore

Δχ=|Δχ(ω)|exp(jφ) (3)

where |Δχ(ω)| is the amplitude of the perturbation and co is the phase shift.

Under the assumption that the electrochemical cell exhibits a linear behaviour (e.g. by maintaining a low enough amplitude of the perturbation), then the transfer function Z is a tensor and equation (1) turns into a matrix equation

ΔYₖ=ΣᵢZ_{i,k}ΔWᵢ (4)

where ΔW and ΔY are complex quantities of the input and output, respectively derived from the generalized quantity of Δχ and Z_{i,k} is the elementary transfer function.

In what follows, the input W_{U} represents the perturbation of the potential between the working electrode and the reference electrode, Y_{I} is the perturbed current and Y_{D} is the perturbed displacement output. Zₑ is the electrical impedance of the electrochemical cell, which turns to the Ohmic resistance R_{Ω} when the imaginary part diminishes (i.e. when the phase shift φ=0). The determination of Ohmic resistance of an electrochemical cell is well known to the skilled person, see, for example, the description in theory of electrochemical impedance spectroscopy. Zₘ is the mechanical impedance of the electrochemical cell.

In step 106, the lock-in amplifiers 28, 30 are used to extract information from the potentially noisy signals of the second electrical parameter measurement signal, i.e. the current measurement, and the mechanical parameter measurement signal, i.e. the displacement measurement, the second electrical parameter signal and the mechanical parameter signal having the same carrier wave form as the periodic perturbation applied in step 102. In particular, the lock-in amplifiers 28, 30 directly measure the quantities Zₘ and Zₑ. However, these quantities are not necessarily equal to the mechanical and the electrical impedance of the active material of interest. Therefore, further transformations are needed to calculate the resistances of the materials.

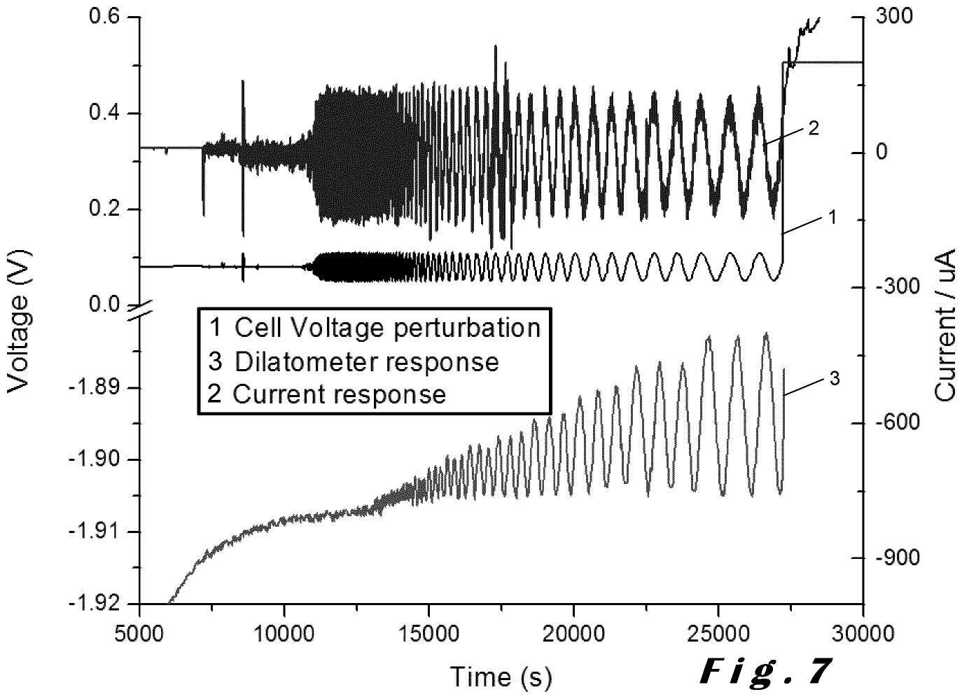

An example of the input/output signals of the measurement device is shown in FIG. 7. Curve 1 represents the potential perturbation at the working electrode 12, curve 2 represents the current response and curve 3 represents the dilatometer response.

In step 108, the extracted signals are transformed into the frequency domain. This may be done using a fast Fourier transform or other known techniques, such as a wavelet analysis. In the illustrated embodiment, steps 106 and 108 are executed simultaneously by the lock-in amplifiers 28, 30, i.e. the lock-in amplifiers 28, 30 both extract the measurement signals and transform these into the frequency domain to determine the complex electrical impedance of the electrochemical cell Zₑ and the complex mechanical impedance of the electrochemical cell Zₘ.

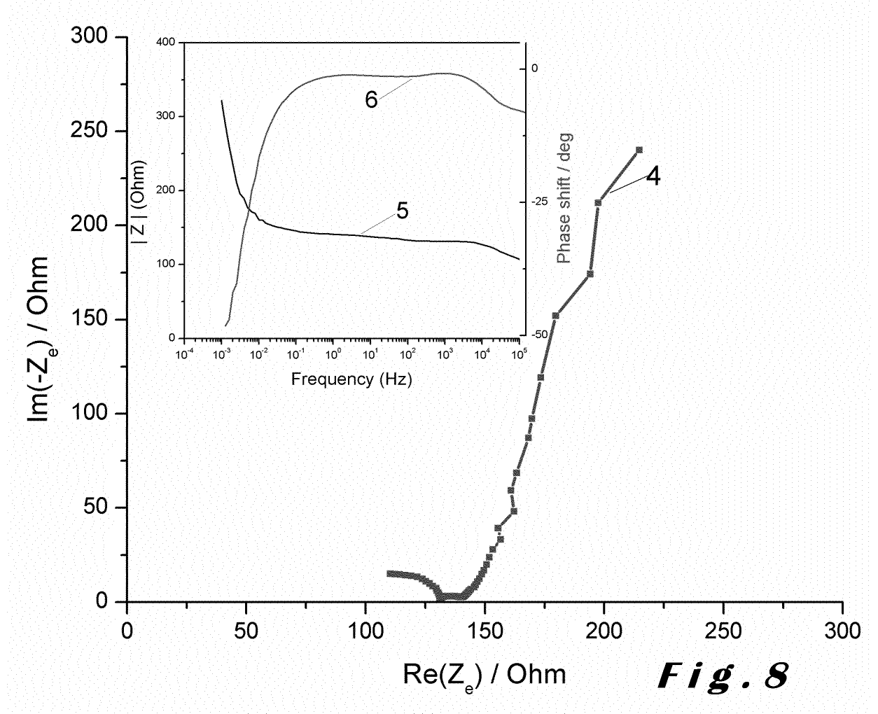

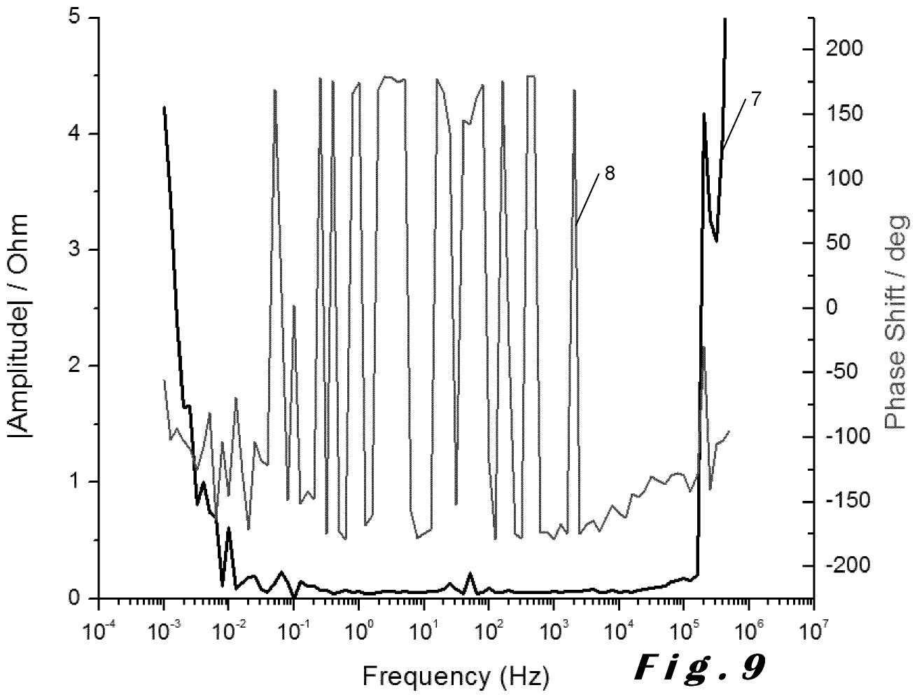

An example of the output signals of the lock-in amplifiers 28, 30 is shown in FIGS. 8 and 9. FIG. 8 shows a Nyquist representation of the complex electrical impedance of the electrochemical cell Zₑ in curve 4 and a Bode representation of the amplitude of Zₑ in curve 5 and the phase of Zₑ in curve 6. FIG. 9 shows a Bode representation of the amplitude of Zₘ in curve 7 and the phase of Zₘ in curve 8. The phase shift of curve 8 seems to be very noise between 10⁻¹-10³ Hz, which means that the mechanical sensitivity of the system is low in this region. Above 10³ Hz the dilatometer is not capable to measure the signal correctly because of an implemented low pass filter. Consequently, the mechanical impedance is worth measuring only in the region 1 mHz-1 Hz for this particular material.

In step 110, the electroactive material electrical complex impedance Z_{E}, the electro-mechanical impedance Z_{ε} and the chemo-mechanical impedance Z_{Li} are determined starting from Zₑ and Zₘ.

The electrical impedance of the electrochemical cell is the sum of the electrical resistance of the active material and the internal Ohmic resistance of the cell Rn (e.g. electrolyte resistance, contact resistance, etc.). The latter is not relevant to the electroactive material therefore it needs to be subtracted. Hence the electrode potential E(V)=W_{U}−Y_{I}R_{Ω} and electroactive material electrical complex impedance Z_{E} are introduced:

Z_{E}=Zₑ−R_{Ω}. (5)

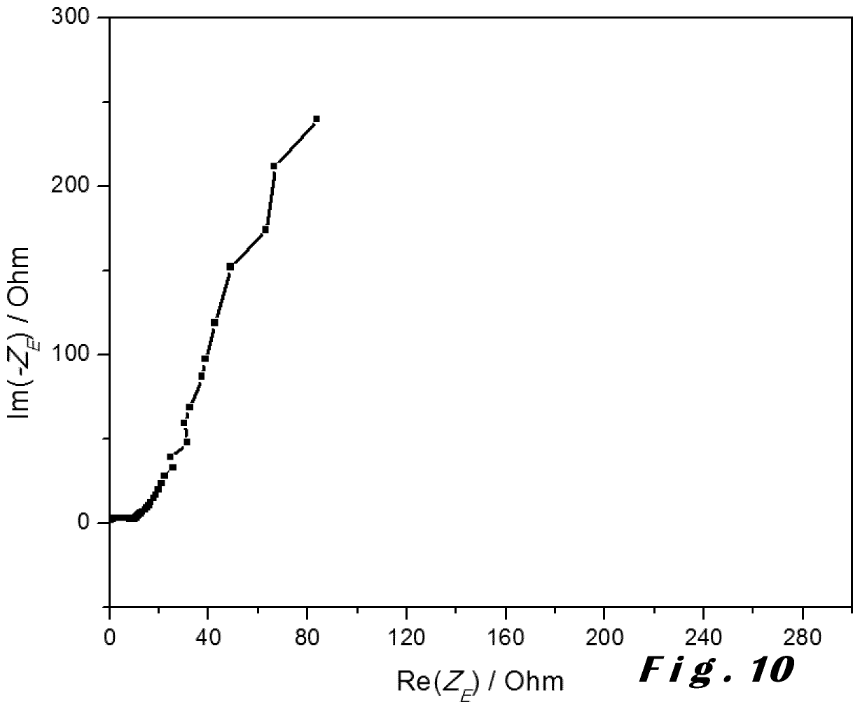

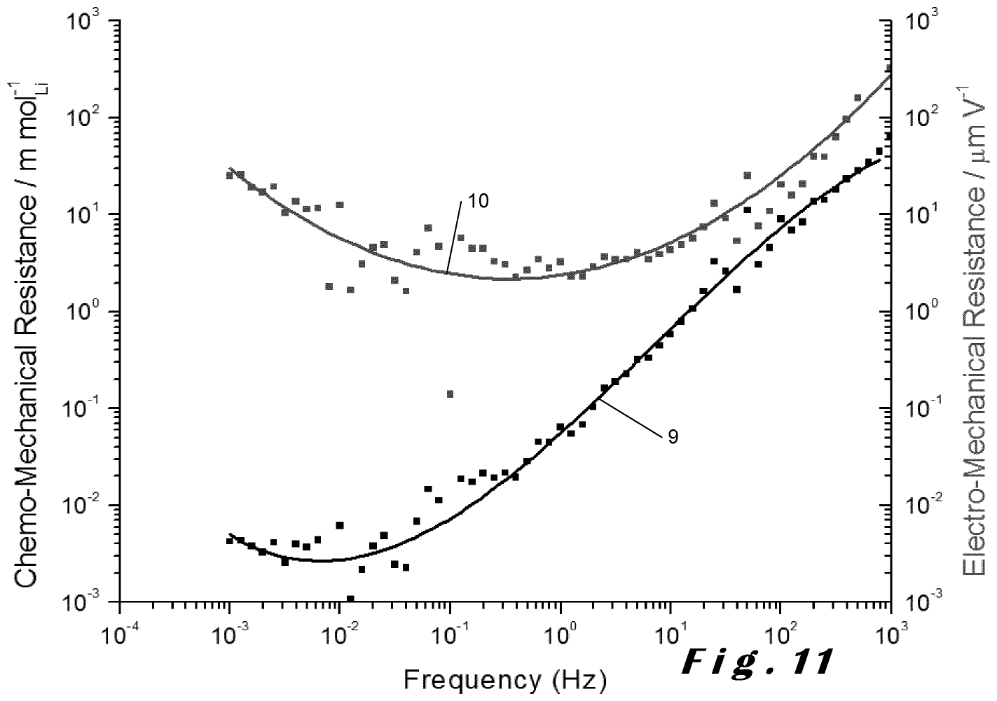

An example of the electroactive material electrical complex impedance Z_{E} is shown in FIG. 10 in a Nyquist representation.

The mechanical signal Y_{D} may, in some embodiments, also need to be converted, because displacement signal may be measured in, for example, volts. Therefore, a monotonous, preferably linear, function is introduced to get the transform the displacement in meter

ε=L(Y_{D})=LY_{D}+L₀ (6)

where ε (expressed in m) is the strain (or stress expressed in Pa in other embodiments) of the material, L is the linear conversion function (e.g. expressed in mV⁻¹) and L₀ is a baseline (expressed m), e.g. steady state, value of the displacement sensor 36.

The electro-mechanical impedance Z_{ε} can be calculated using the equation

$${Z}_{ɛ} = \frac{Δɛ}{Δ E} = {LZ}_{m} \frac{{Z}_{e}}{{Z}_{e} - {R}_{Ω}} . \qquad ( 7 )$$

If the conversion function is not linear, then its Laplace transform is required to determine the electro-mechanical impedance Z_{ε} and should be incorporated in equation (7). The electro-mechanical impedance reflects the resistance of the material expansion to a certain thermodynamic force i.e. the electrode potential. An example of the electro-mechanical impedance Z_{ε} is shown in FIG. 11 in curve 9.

Alternatively, in cases where the measurement device determines the complex impedance quantity

$${Z}_{I} = \frac{Δɛ}{Δ {Y}_{I}} , \qquad ( 9 )$$

where Y_{I} is the current signal, the electro-mechanical impedance Z_{ε} can be determined as follows

$${Z}_{ɛ} = \frac{Δɛ}{Δ {Y}_{I}} \frac{Δ {Y}_{I}}{Δ E} = {LZ}_{I} {Z}_{E}^{- 1} \qquad ( 10 )$$

Another important characteristic of the active material is the resistance against a certain chemical change (i.e. irrespective of the applied thermodynamic force). For electroactive materials it can be calculated from the Faradaic charge. In the basic theory of electrochemical impedance spectroscopy every electrode has a certain capacity, which is charged and discharged during the perturbation of the potential or current. This so called double layer charging current is not converted into material reduction or oxidation, therefore this part needs to be subtracted. The chemo-mechanical impedance Z_{Li} can be determined from the following equation

$${Z}_{Li} = \frac{Δɛ}{Δ {c}_{Li}} ( ω ) = j ω F \frac{{Z}_{ɛ}}{1 - {Z}_{ɛ} j ω {C}_{dl}} \qquad ( 11 )$$

where C_{dl} is the double layer capacitance which may be determined from the Nyquist or Bode plot of Zₑ using standard electrochemical impedance spectroscopy calculations, c_{Li} is the Li-ion concentration in the working electro active material, and F is the Faraday constant.

The impedances quantify the effective resistance of the electrochemical cell. By determining the electrical impedance, the mechanical impedance and the chemo-mechanical impedance, it is possible to ascertain the effects of the applied periodic perturbation on the various effective resistances using the equations above.

As briefly described above, the method 100 may be used sequentially with different predetermined carrier wave forms to determine behaviour of the electrochemical cell at different frequencies.

In a first approach, a frequency sweep is used which from the highest value (e.g. 100 kHz) and goes down to the minimum value (e.g. 1 mHz). Multiple periods of a single perturbation are applied at a single frequency value and after the measurement of Zₑ, Zₘ it steps to the next predefined single frequency value. The number of the predefined frequency values is at least 1 in every decade change, but preferably at least 5. With this approach down to about 1 Hz, the measurement is relatively fast, meaning that the state of the system does not change much during the measurements. However, systematic errors may occur so it is advisable to repeat the frequency scan at least two times.

In a second approach, alternative frequency scans are applied, for example by randomly selecting multiple single frequencies from the frequency range between the minimum and maximum values. This method may be free from systematic errors, but the state of the system may change with time.

In a third approach, as described above, the carrier wave is itself a superposition of multiple frequencies.

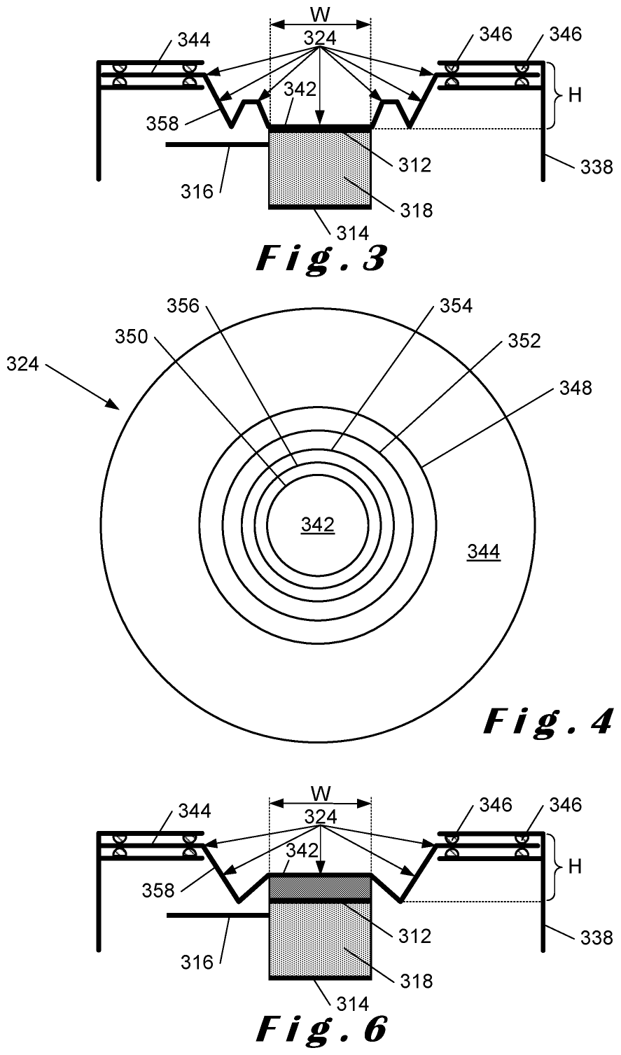

FIG. 3 shows a schematic representation of a measurement device according to the present invention. Elements or components previously described with reference to FIG. 1 bear the same last two digits but preceded by a ‘3’.

The measurement device is also based on a typical three-electrode system with the working electrode 312, the counter electrode 314, the reference electrode 316 and the separator 318. These components are enclosed in a housing 338 to shield the electrochemical cell from the outside environment. The housing 338 is provided with an opening that is covered by the membrane 324, which membrane also closes the circuit. The membrane 324 is fixed to the housing 338 by means of sealing rings 346 that fix the outer region 344 of the membrane 324. It will be appreciated that other methods are available to fix the outer region 344 of the membrane 324 to the housing 338, e.g. glue. Although not shown, various other components of the measurement device may also be included in the housing 338, e.g. the lock-in amplifiers, the controller, etc.

The measurement device is provided with a contactless displacement sensor (not shown) which uses a laser interference technique to measure the displacement of the working electrode 312. Specifically, the contactless displacement sensor measures a vertical translation of the inner region 342 of the membrane 324, the inner region 342 being the area on which the working electrode 312 is attached, optionally by an intermediary of a current collector (not shown) as in the measurement device of FIG. 1, on the inside of the housing 338. In view of the use laser interference, it is advantageous in case the outer surface of the membrane 324, at least the inner region 342, is reflective.

The inner region 342 and the outer region 344 are connected to one another by a middle region 358. The middle region 358 is connected to the inner region 342 by means of a folding line 350 and to the outer region 344 by means of a folding line 348. In an embodiment, the middle region 358 has a width w of at least 0.1 mm and at most 5 mm, preferably at most 1 mm. In the illustrated embodiment, there is a height difference H between the inner region 342 and the outer region 344. The height H is at least 0.05 mm and at most 1 mm, preferably at most 0.5 mm. It will be appreciated that the inner region 342 may also be located higher than the outer region 344.

The middle region 358 is provided with three folding lines 352, 354, 356 in the illustrated embodiment of FIGS. 3 and 4. These folding lines 352, 354, 356 ensure that the inner region 342 can move more freely in the vertical direction. In particular, the vertical movement of the inner region 342 will cause the sections of the middle region 358 between the folding lines 352, 354, 356 to change their relative orientation. This makes it easier for the inner region 342 to move in the vertical direction when compared to a wholly flat membrane 324.

It will be readily appreciated that a minimum of three folding lines 348, 350, 354 is required in order to minimise distortions in the displacement of the working electrode 312 as illustrated in the alternative embodiment shown in FIG. 6.

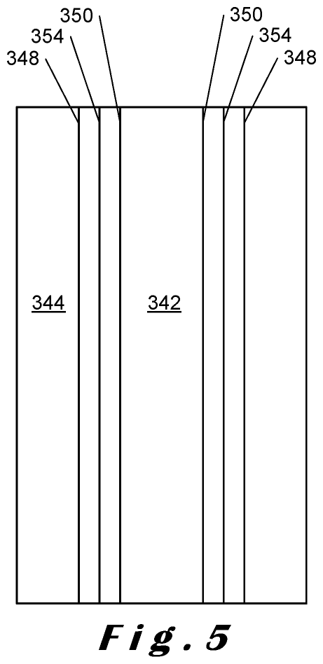

A top view of the membrane 324 is shown in FIG. 4. This illustrates that the membrane 324 has a cylindrical symmetry. However, although a membrane 324 with a cylindrical symmetry is preferred, other configurations are also possible. For example, the planar symmetry illustrated in FIG. 5 for use with the device shown in FIG. 6.

Although aspects of the present disclosure have been described with respect to specific embodiments, it will be readily appreciated that these aspects may be implemented in other forms within the scope of the invention as defined by the claims.

1. A computer-implemented method for electrochemical impedance spectroscopy of an electrochemical cell including a working electrode and at least one second electrode, the method comprising the steps of:
a) applying a periodic perturbation with a predetermined carrier wave form on a first electrical parameter of the electrochemical cell, the first electrical parameter being one of a potential and a current;
b) simultaneously measuring an influence of the periodic perturbation on a second electrical parameter of the electrochemical cell and on a mechanical parameter of the working electrode, the second electrical parameter being the other one of the potential and the current, the mechanical parameter being one of a displacement and a stress;
c) extracting, using a first lock-in amplifier, from the second electrical parameter measurement signal a second electrical parameter signal with the predetermined carrier wave form; and
d) extracting, using a second lock-in amplifier, from the mechanical parameter measurement signal a mechanical parameter signal with the predetermined carrier wave form.

2. The computer-implemented method according to claim 1, wherein the method further comprises the following step:
e) transforming the second electrical parameter signal and the mechanical parameter signal into the frequency domain to determine a coupling between the electrical parameters and the mechanical parameter of the electrochemical cell.

3. The computer-implemented method according to claim 1, wherein step a) comprises applying the periodic perturbation to the potential, the periodic perturbation having an amplitude between 1 to 50 mV.

4. The computer-implemented method according to claim 3, wherein the method further comprises the step of determining the electroactive material electrical complex impedance Z_{E}, the electro-mechanical impedance Z_{ε} and the chemo-mechanical impedance Z_{Li} are determined using the following equations
$${Z}_{E} = \frac{Δ E}{Δ I} = {Z}_{e} - {R}_{Ω} ;$$
$${Z}_{ɛ} = \frac{Δɛ}{Δ E} = {LZ}_{m} \frac{{Z}_{e}}{{Z}_{e} - {R}_{Ω}} or {Z}_{ɛ} = L \frac{Δɛ}{Δ {Y}_{I}} \frac{Δ {Y}_{I}}{Δ E} = {LZ}_{I} {Z}_{E}^{- 1} ; and$$
$${Z}_{Li} = \frac{Δɛ}{Δ {c}_{Li}} ( ω ) = j ω F \frac{{Z}_{ɛ}}{1 - {Z}_{ɛ} j ω {C}_{dl}} ,$$
where Zₑ is the electrical impedance of the electrochemical cell, Zₘ is the mechanical impedance of the electrochemical cell, E is the electrode potential, R_{Ω} is the Ohmic drop, v is the strain, C_{dl} is the double layer capacitance, L is a conversion factor, c_{Li} is a Li-ion concentration in the working electro-active material, F is the Faraday constant, j is the imaginary number and ω is the frequency of the periodic perturbation.

5. The computer-implemented method according to claim 1, wherein step b) comprises any one of the following:
using a mechanical coupler to measure the displacement;
using a laser interference technique to measure the displacement; and
using a beam bending technique to measure the stress.

6. The computer-implemented method according to claim 1, wherein the periodic perturbation has a frequency between 0.1 mHz and 10 MHz.

7. The computer-implemented method according to claim 1, wherein step a) comprises choosing the predetermined carrier wave form as a signal including a plurality of different frequencies.

8. A measurement device for electrochemical impedance spectroscopy, the device comprising:
an electrochemical cell including a working electrode and at least one second electrode;
a potential sensor connected to the working electrode and the at least one second electrode to measure a potential of the electrochemical cell;
a current sensor connected to the working electrode and the at least one second electrode to measure a current of the electrochemical cell;
a mechanical sensor configured to measure a mechanical parameter of the working electrode, the mechanical parameter being one of a displacement and a stress;
perturbation means for periodically perturbing a first electrical parameter of the electrochemical cell, the first electrical parameter being one of the potential and the current;
a first lock-in amplifier connected to one of the potential sensor and the current sensor;
a second lock-in amplifier connected to the mechanical sensor; and
a controller configured to execute the steps of the method according to any one of the preceding claims.

9. The measurement device according to claim 8, wherein the at least one second electrode comprises a counter electrode and a reference electrode, the potential sensor being connected to the reference electrode and the current sensor being connected to the counter electrode.

10. The measurement device according to claim 8, wherein the mechanical sensor is a contactless displacement sensor.

11. The measurement device according to claim 8, wherein the electrochemical cell is one of a Li-ion battery, a Na-ion battery and a solid-state Li battery or where the electrochemical cell comprises an electroactive material with a measurable volume change in use.

12. The measurement device according to claim 8, wherein the device further comprises:
a housing having an opening; and
a flexible membrane to cover said opening, the flexible membrane including an outer region fixedly attached to the housing, a substantially flat inner region to which the working electrode is attached and a middle region connecting the outer region and the inner region wherein the middle region is provided with at least one folding line.

13. The measurement device according to claim 12, wherein the flexible membrane has a cylindrical symmetry.

14. The measurement device according to claim 12, wherein the flexible membrane is made of a conducting material.

15. The measurement device according to claim 12, wherein an outer surface of the flexible membrane opposite to the working electrode is reflective.
